(19) United States
(12) Patent Application Publication
(10) Pub. No.: US 2026/0214815 A1
(43) Pub. Date: Jul. 23, 2026

(54) HOUSING FOR AN ELECTRICAL DEVICE AND METHOD FOR THE PRODUCTION THEREOF

(71) Applicant: Phoenix Contact GmbH & Co. KG, Blomberg (DE)

(72) Inventors: Michael PETER, Lage (DE); Manuela PAUS, Münster (DE); Kilian KLAGES, Detmold (DE)

(21) Appl. No.: 19/140,363

(22) PCT Filed: Dec. 5, 2023
(86) PCT No.: PCT/EP2023/084271

§ 371 Date: Jun. 18, 2025

(30) Foreign Application Priority Data
Dec. 22, 2022 (BE) BE2022/6070

(51) Int. Cl. H05K 5/02; B41J 3/28; B41J 3/407; B41J 11/06; B41J 29/13; C08J 11/10; C09D 101/08; C09D 103/02; C09D 167/02; C09D 167/04

(52) U.S. Cl. CPC H05K 5/02; B41J 3/28; B41J 3/407; B41J 11/06; B41J 29/13; C08J 11/10; C09D 101/08; C09D 103/02; C09D 167/02; C09D 167/04

(57) ABSTRACT

The invention relates to a housing (1A-1F) for an electric device (2), said housing being at least partly made of a material that comprises a plastic which is a polymer secondary raw material and/or a biodegradable polymer and/or a bio-based polymer.

### CROSS-REFERENCE TO PRIOR APPLICATIONS

This application is a U.S. National Phase application under 35 U.S.C. § 371 of International Application No. PCT/EP2023/084271, filed on Dec. 5, 2023, and claims benefit to Belgian Patent Application No. BE2022/6070, filed on Dec. 22, 2022. The International Application was published in German on Jun. 27, 2024 as WO 2024/132494 A1 under PCT Article 21(2).

### FIELD

The invention relates to a housing for an electrical device, to an electrical device having such a housing, to a method for producing a housing for an electrical device and to a method for producing such an electrical device.

### BACKGROUND

Housings for electrical devices have established importance in particular in the electrotechnical industry, for example where they hold in particular electronic components, printed circuit board assemblies and/or conductors, which may be electrical cables, photonic conductors and conductor tracks depleted on a circuit carrier, at or in various positions. These are typically supposed to meet the high requirements that are usually placed on the intended use within the industrial sector. For example, they are in particular configured and designed to protect the electronic components, printed circuit boards and/or conductors arranged on or in the housing serving, for example, as a main body, from the effects of external environmental influences. Furthermore, they are regularly supposed to ensure functional reliability over a long service life, which is typical for equipment in the industrial sector, and also trouble-free operation of a system comprising the housing. At the same time, they should not pose a health risk.

In GB 2 401 084 A, a printer housing is made of a biodegradable material, namely water-soluble cellulose. The disadvantage here is that a wax paper coating is necessary to protect against water, which makes production complex, and, due to the mechanical properties of the material, only a relatively small portion of the printer housing can be produced in this way.

Typically, housings for electrical devices, such as the printer housing mentioned by way of example, are made of a polymer or metal. Polymers established themselves very early on in the industrial sector as economical and easily moldable materials for various areas and tasks and cover a very wide range of possible applications. However, the problem with plastic materials is that they can have a high environmental impact.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a schematic sectional view of an electrical device in the form of a printer having a housing;

FIG. 2 shows a method for producing a housing for an electrical device and the electrical device;

FIG. 3 is a schematic view of a further electrical device in the form of a printer having a housing;

FIG. 4 is a schematic view of a housing in the form of an input magazine;

FIG. 5 is a schematic view of a further electrical device in the form of a battery module having a housing;

FIG. 6 is a schematic view of a further electrical device in the form of a power supply unit having a housing; and

FIG. 7 is a schematic view of a further electrical device for mounting on a mounting rail.

### DETAILED DESCRIPTION

In an embodiment, the present invention improves the environmental balance of a housing for an electrical device and its production.

Accordingly, a housing is provided, in particular for an electrical device, which is at least partially made from a material comprising a plastics material that is a polymeric secondary raw material and/or is a bio-based polymer (e.g., made from synthesis gas and/or liquids and/or more generally reactants made from renewable and/or biological sources) and/or is a biodegradable polymer.

This is based on choosing from a selection of plastics materials that are used, either on their own or in combination, to increase the environmental compatibility of a housing or to reduce its impact on the environment. This allows for a housing whose environmental balance is significantly improved. The invention achieves the object posed for it by means of a material approach to reduce the environmental impact. To achieve the object, the invention departs from an approach which reduces the use of a polymer obtained from a fossil raw material simply by changing the geometry of the housing so as to minimize the use of the fossil raw materials. Furthermore, the invention shifts away from the approach of replacing a plastics material with another material, such as a metal.

This is achieved by providing a selection of plastics materials that are recycled and/or produced from renewable raw materials and/or are biodegradable. The selection is therefore not limited to a specific plastics material from those mentioned above, and therefore they can also be combined with one another.

The material can consist of at least one of the aforementioned plastics materials, but may also contain other substances added to the material, such as additives or other polymers or polymer components. Furthermore, composite materials can also be used for the material. Furthermore, it is possible to mix the aforementioned plastics materials with other components, for example additives or primary polymers.

The housing described herein makes it possible not only to significantly reduce the environmental impact but also to significantly reduce the impact on raw material resources. Furthermore, the housing can meet the-sometimes-high requirements that are placed on the usability thereof, e.g., with regard to electrical breakdown safety, fire protection and/or electrical insulation, which are usually realized with primary materials.

Optionally, the material comprises a plurality of different plastics materials. Each of the plurality of different plastics materials can be a polymeric secondary raw material and/or made from synthesis gas/liquids/reactants made from renewable and/or biological sources and/or can be biodegradable. For example, the material comprises a polymeric secondary raw material and a renewable raw material, or the material comprises a polymeric secondary raw material and a biodegradable raw material, or the material comprises a renewable raw material and a biodegradable raw material, or the material comprises a polymeric secondary raw material and a renewable raw material and a biodegradable raw material. Optionally, the same plastics material of the material can be both a polymeric secondary raw material and a renewable raw material, or the same plastics material is both a polymeric secondary raw material and a biodegradable raw material, or the same plastics material is both a renewable raw material and a biodegradable raw material, or the same plastics material is a polymeric secondary raw material as well as a renewable raw material and a biodegradable raw material. This allows particularly environmentally friendly housings to be provided.

The housing can therefore be made from a plurality of different materials, each of which can comprise a plastics that is a polymeric secondary raw material, is made from synthesis gas/liquids/reactants made from renewable and/or biological sources and/or is biodegradable. This makes it possible to create a housing that is environmentally friendly and at the same time particularly well adapted to application-specific requirements. For example, the housing has a first housing part or a first housing portion made of such a first material and a second housing part or a second housing portion made of such a first material. The housing portions can be interlockingly connected or integrally bonded to one another.

The polymeric secondary raw material can be a conventional and/or chemically recycled thermoplastic. Conventionally recycled thermoplastics are, for example, mechanically recycled and/or produced by melting. Conventionally recycled thermoplastics typically differ from corresponding primary, i.e., non-recycled, thermoplastics by their correspondingly shorter polymer chains. Conventionally recycled materials regularly differ from standard materials by their additional thermal stress, as the polymers are typically melted at least one more time than the original standard material. If additional granulation processes are still provided before the material is processed/used for the second time, the additional thermal stress/damage may be further increased. Certificates for a reduced CO₂ content are usually issued for chemically recycled materials. Usually, this can be used to subsequently prove a corresponding CO₂ reduction.

For example, at least 25 wt. % of the material consists of the plastics material that is a conventionally and/or chemically recycled thermoplastic, in particular at least 50 wt. % or even 100 wt. %. This enables a substantial improvement in the environmental balance, the so-called CO₂ footprint of the material.

Optionally, the polymeric secondary raw material is a conventionally recycled thermoplastic, which can be an engineering thermoplastic. For example, the polymeric secondary raw material is a conventionally recycled thermoplastic and/or is selected from the group of polycarbonate, polyamide, polyethylene, polyethylene terephthalate, polyvinyl chloride and polypropylene. These materials provide particularly good properties for many fields of use.

Optionally, 10 to 100 wt. % (or 10 to 80 wt. %) of the material consists of the plastics material produced from synthesis gas/liquids/reactants made from renewable and/or biological sources. This allows a particularly resource-saving housing to be provided.

For example, the plastics material of the material is produced from synthesis gas/liquids/reactants made from renewable and/or biological sources, wherein the renewable raw material is selected from sugar, starch, protein, cellulose, lignin, fat and/or vegetable oil, in particular castor oil. This generally includes renewable or biologically produced synthesis gases and synthesis liquids that are used as reactants for formulating/representing the plastics material (e.g., biogas, biomethanol, bioliquids, organic waste, etc.). This allows for an environmentally friendly and simultaneously robust housing.

The plastics material of the material can be produced from synthesis gas/liquids/reactants made from renewable and/or biological sources and can be in the form of polylactide, polyhydroxyalkanoate, cellulose derivative, in particular cellulose ester or cellulose butyrate, polyethylene, starch derivative, polyamide 4.6 or polycarbonate. This also allows for an environmentally friendly and simultaneously robust housing.

Optionally, the plastics material of the material is biodegradable and can be in the form of polybutylene adipate terephthalate, polyhydroxyalkanoate, polylactide, starch blend or polyester. This means that the housing can be easily composted after use, optionally also avoiding composting additives. This in particular makes it possible to dispose of it in a very environmentally friendly manner.

The housing may further comprise a fastening point for a component. Optionally, the fastening point is (rigidly) connected to the rest of the housing via a predetermined breaking point. This allows the component to be easily broken off before recycling so that the housing material can be recycled as best as possible.

In one embodiment, the housing is designed as a printer housing. The housing may have an opening. The opening can be designed and configured for the insertion and/or removal of a medium to be printed on. The medium to be printed on can be a film, a plate, a strip or a sign. The medium to be printed on can be rigid.

According to one aspect, an electrical device is provided. The electrical device comprises the housing according to any embodiment described herein. The electrical device may comprise one or more electrical and/or electronic components arranged in and/or on the housing. The housing can be designed as a conductor support for conductors and, for example, comprise an electrical component in the form of a conductor.

The electrical device comprises, for example, a printing unit for printing on a medium to be printed on. As already mentioned, the medium to be printed on can be a film, a plate, a strip or a sign. The medium to be printed on can be rigid.

The electrical device may further comprise a media receptacle. The media receptacle is designed and configured, for example, to hold and/or convey the medium to be printed on while it is printed on by the printing unit. The media holder and the printing unit can be designed so that rigid media to be printed on can be printed on. For example, the electrical device has an input magazine and an output magazine for the rigid media to be printed on.

In one embodiment, the media holder and/or the printing unit are designed such that plastics-or metal-based rigid media to be printed on in the form of plates, strips or signs can be printed on.

One or more movable parts may be arranged in or on the housing of the device. Optionally, the movable part or the movable parts is/are also at least partially made of a material comprising a plastics material that is a polymeric secondary raw material, is made from synthesis gas/liquids/reactants made from renewable and/or biological sources and/or is biodegradable. In particular, the movable part or the movable parts can be made from the same material as the housing. This allows for an even better environmental balance and also simplified production.

Optionally, at least one component arranged in or on the housing, in particular electrical and/or electronic component, is fastened to the housing via a predetermined breaking point of the housing. This allows the component to be easily broken off and quickly and easily sorted and separated when recycling the device.

According to one aspect, a method for producing a housing for a device, in particular an electrical device, is specified. The method involves providing a material comprising a plastics material, wherein the plastics material is produced by recycling a thermoplastic, is produced from synthesis gas/liquids/reactants made from renewable and/or biological sources and/or is biodegradable, and shaping the housing from the material, at least in part, optionally in full. As regards the advantages, reference is made to the above statements regarding the housing. The method can be used to produce the housing in accordance with any of the embodiments described herein.

To produce the housing, a polymer can be selected from a plurality of polymers, in particular polycarbonate, acrylonitrile-butadiene-styrene, polymethyl methacrylate, polystyrene, polyetherimide, polyethersulfone, polysulfone, polyphenylene oxide, styrene acrylonitrile, polystyrene, polymethyl methacrylate, polypropylene, polyethylene, thermoplastic polyurethane, polyacetal, polyethylene terephthalate, polybutylene terephthalate, polyarylates, polysulfones, polyphenylene sulfide, polyether ketone, polyimides, polyetherimide, polyphthalamide, polyoxymethylene, polyether ether ketone and/or polyamide, for example PA 66.

Optionally, the plastics material is produced by chemically recycling a thermoplastic. This allows the plastics material to be a particularly high-performance and high-quality plastics material while at the same time having a particularly positive environmental balance. An alternative or additional conventional recycling process may include shredding.

Chemical recycling includes, for example, solvolysis, depolymerization, pyrolysis and/or gasification. This enables particularly high-quality recycled thermoplastics to be achieved.

According to one aspect, a method for producing a (particularly electronic) device is provided. The method involves producing a housing according to the method described above in any desired embodiment and arranging one or more (e.g., electrical and/or electronic) components in the housing.

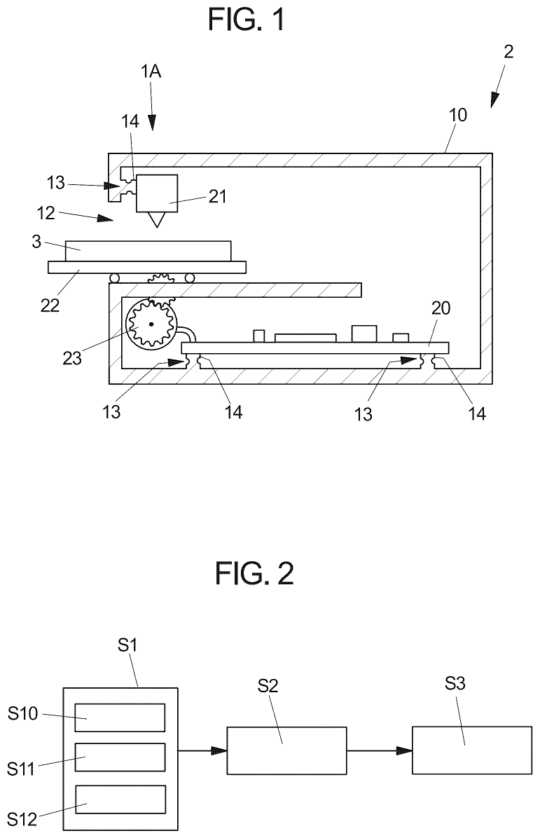

FIG. 1 shows an electrical device 2 in the form of a printer for printing on media 3 to be printed on. FIG. 1 shows an arrangement of the electrical device 2 together with a medium 3 to be printed on.

The electrical device 2 comprises a housing 1A. The housing 1A is generally at least partially made of a material comprising a plastics material that (a) is a polymeric secondary raw material and/or (b) is made of synthesis gas/liquids/reactants made from renewable and/or biological sources and/or (c) is biodegradable.

The polymeric secondary raw material is, for example, a conventionally recycled thermoplastic (e.g., mechanically and/or by melting) and/or a chemically recycled thermoplastic. For example, at least 25 wt. % of the material consists of the polymeric secondary raw material. The polymeric secondary raw material can be an engineering thermoplastic, in particular polycarbonate, polyamide, polyethylene, polyethylene terephthalate, polyvinyl chloride or polypropylene. Thermoplastics have the advantageous property of good formability and processability since they can soften to the point of flowing, for example, when heat is applied, and are therefore easy to shape. After a cooling phase, they become solid again and retain their shape.

Industrial plastics waste is often available in large quantities and is usually pure-grade, which means that sorting or cleaning effort can be minimized and it is then immediately available for recycling. For example, it is comminuted and can then be reused to form the housing 1A.

Furthermore, 10 to 100 wt. % of the material can consist of the plastics material produced from synthesis gas/liquids/reactants made from renewable and/or biological sources. The renewable raw material can be sugar, starch, protein, cellulose, lignin, fat and/or vegetable oil. In particular, the renewable raw material can be castor oil. Bio-based polymers can also be referred to as engineering biopolymers and can be produced from biogenic raw materials, preferably renewable plant-based raw materials. Biowaste can also be used for this purpose, whereby sustainability is or can be further increased. Renewable raw materials, in particular rapeseed and corn, for example, are available and exist or can be grown in large quantities. A bio-based polymer that is also biodegradable is particularly environmentally friendly. Examples of bio-based polymers are poly butyrate adipate terephthalate (PBAT), so-called starch-based biodegradable blends or polylactide (PLA), polyhydroxyalkanoates (PHA), cellulose derivatives, e.g., cellulose esters (CA) and cellulose butyrate (CAB), so-called biodegradable polyesters as well as starch derivatives. They also include bio-polyethylene and can correspond to the properties of a conventional polyethylene based on a fossil raw material (primary polymer).

Furthermore, the plastics material of the material can be biodegradable and can be in the form of, for example, polybutylene adipate terephthalate, polyhydroxyalkanoate, polylactide, starch blend or polyester. A biodegradable portion of the material can be detected by carbon detection. A material is biodegradable in particular when such degradation takes place by means of a chemical process in which microorganisms present in the environment convert the material into natural substances such as water, carbon dioxide and compost (artificial additives in particular not being required). The process of biodegradation depends on the environmental conditions (e.g. location or temperature), the material and the applications. Biodegradable polymers include PBAT, PLA and PHA, among others.

The biodegradable plastics materials can be enriched with additional properties by means of additives based on fossil raw materials or renewable raw materials so that, compared with conventional polymers, further potentially specific material properties can be produced with regard to the desired markability and/or printability, light resistance, water vapor permeability or biodegradability. These polymers therefore open up a wide range of uses through specifically adapting the material.

In the example in FIG. 1, the material of the housing 1A consists of recycled starch blend.

The housing 1A has an outer wall 10 which defines an interior space. A plurality of electrical components 20 are arranged in the interior space. In the example shown, electrical components 20 in the form of a printed circuit board having a plurality of electronic components are arranged in the housing 1A. Furthermore, a printing unit 21 is arranged in the housing 1A, by means of which unit the medium 3 to be printed on can be printed on. The printing unit 21 is optionally movably mounted in the housing 1A, for example in a direction perpendicular to a conveying direction of the medium 3 to be printed on in the housing 1A. The printing unit 21 can also represent an electrical component.

The printing unit 21 provides thermal transfer printing, inkjet printing and/or laser marking.

When applying a marking by laser marking, a color and/or contrast change can be created by laser radiation on the surface in question. This is achieved, for example, by carbonization of the polymer or the polymer composition. This allows for precise and fast creation of a marking. Furthermore, other auxiliary materials, especially printing media such as ink, are not necessary. Furthermore, a marking can be applied by other means, in particular by means of ink, for example, in particular by means of a penplotter or inkjet printing, for example, or using thermal transfer printing.

The housing 1A has an opening 12. The opening 12 is used here to insert the medium 3 to be printed on.

The electrical device 2 further comprises a media holder 22 on which the medium 3 to be printed on can be arranged and is arranged according to FIG. 1. In the example shown, the media holder 22 is movable relative to the housing 1A. In the present case, the medium 3 to be printed on that is arranged on the media holder 22 can be displaced relative to the printing unit 21 as a result of a relative movement between the media holder 22 and the housing 1A.

In order to make the media holder 22 move, the electrical device 2 has a drive mechanism having a plurality of parts 23 which can move relative to the housing 1A, with two gears being illustrated here as an example. In the example shown, the drive mechanism comprises an electric motor for making the movable parts 23 move. The electric motor is electrically connected to further electrical components, in this case the circuit board, via conductors. The housing 1A thus also serves as a conductor support comprising a conductor, a main body, namely the housing 1A, on which the conductor is arranged, wherein the housing 1A has a portion (here the portion shown in FIG. 1) which consists of a polymer composition or comprises such a polymer composition, wherein at least one component of the polymer composition consists of at least one of the following substances or comprises at least one of the following substances: polymeric secondary raw material, biodegradable polymer, bio-based polymer (i.e., produced from synthesis gas/liquids/reactants made from renewable and/or biological sources).

The polymer composition may be, or be based on, a thermoplastic polymer, in particular a polypropylene or a polyethylene, a polyethylene terephthalate, a polyvinyl chloride or a combination of at least two thereof. The polymeric secondary raw material may be or comprise a polymer recyclate, in particular a reused and/or recycled polymer.

The polymer recyclate may be made from or comprise a post-industrial material. The polymer recyclate can have the same material properties as the primary recyclate on which it is based. At least one additive, in particular another polymer and/or a masterbatch, can be added to the polymeric secondary raw material. The masterbatch is, for example, an additive or a composition of additives in the form of granules, in particular with an added colorant. This is used for coloring purposes or to change the material properties. Masterbatches make it possible to intrinsically concentrate several additives. Compared to powder additives, masterbatches can increase technical process reliability and ensure good processability. For example, in line with requirements, UV stabilization, flame protection, antistatic or antiblocking action can be provided in addition to coloring. Other often important material properties are, in particular, chemical, e.g., relating to resistance to particularly aggressive media, odor formation, environmental and health neutrality, and the like; thermal, e.g., relating to a melting and long-term use temperature as well as a thermal expansion coefficient; mechanical, e.g., relating to a specific density, being crystalline or amorphous, resistance to fatigue, the achievement of a desired stiffness, hardness, strength, and/or the like.

The biodegradable polymer can be based on or comprise a cellulose acetate, in particular a secondary acetate obtained therefrom, preferably a diacetate, wherein in particular at least the bio-based polymer is configured and designed as a drop-in polymer, wherein in particular at least the biodegradable polymer is UV-resistant.

Polymers obtained from fossil raw materials can also be referred to as polymeric primary raw materials or primary polymers. Accordingly, polymers that are obtained from primary polymers by recycling can be referred to as polymeric secondary raw materials or secondary polymers. These can, for example and in particular, have a chemical structure specific to them, e.g. molecular chains, by means of which they can be distinguished from primary materials.

In general, at least one component can be fastened to the housing 1A via predetermined breaking points 13. In the present case, a plurality of components, namely the circuit board and the printing unit 21, are fastened to the housing 1A via predetermined breaking points 13. In each case, a predetermined breaking point 13 connects a fastening point 14 to the rest of the housing 1A. The components are rigidly connected to the respective fastening points 14. For recycling purposes, the corresponding component can then be easily separated from the housing 1A by destroying the predetermined breaking points 13, for example by manually breaking it out.

Further components, in particular mechatronic components, can also be made of a material created as described herein, in particular gears, holding plates, cover panels, locking hooks, covers, safety guards, decorative components, sensor housings, motor housings and/or the like.

FIG. 2 shows a method for producing a housing (e.g., the housing 1A according to FIG. 1) for a device, in particular an electrical device (e.g., the electrical device 2 according to FIG. 1), and for producing such a device (in particular such an electrical device). The method comprises the following steps.

In a first step, step S1, a material is provided. The material comprises or consists of a plastics material. The plastics material is produced in a step S10 by recycling, in particular chemically recycling, a thermoplastic, is produced from a renewable raw material in a step S11, and/or provided in the form of a biodegradable plastics material in a step S12. The chemical recycling of the thermoplastic in step S10 involves, for example, solvolysis, depolymerization, pyrolysis and/or gasification. To avoid repetition, reference is made here to the possible properties and compositions of the material described elsewhere herein.

In a further step, step S2, the housing is shaped at least partially, in particular completely, from the material, for example by primary shaping and/or by reshaping. For shaping, an injection mold can be provided into which the material is introduced by plastics injection molding. The housing is then ready.

In order to produce the electronic device, the method further comprises a further step, step S3, in which at least one (in particular electrical and/or electronic) component is arranged in the housing. The component can be fastened to appropriate fastening points, at which predetermined breaking points can in particular be provided.

It should be noted that the method can involve recycling a polymer by breaking it down by pyrolysis into its original monomers or other materials that can be recycled, in particular petrochemically. The latter include methanol and synthesis gases, for example. In order to obtain monomers, the recycling process can be carried out with a pure-grade plastics material. This makes it possible to recover petrochemical raw materials as well as monomers. Furthermore, it is possible to use degradative extrusion to obtain gases, waxes and oils that are equivalent to raw materials and can be recycled accordingly from, in particular mixed, plastics waste. It is thus also possible to recycle polymers whose materials are difficult to separate.

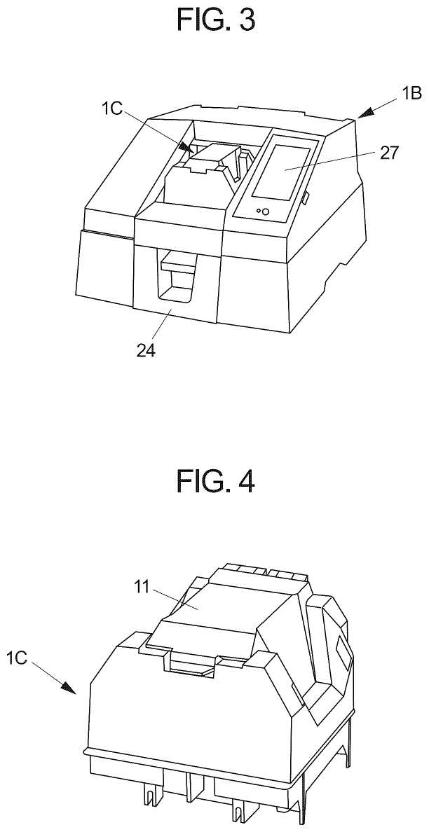

FIG. 3 shows another example of a housing 1B for an electrical device in the form of a printer. A removable input magazine is arranged on the housing 1B and in turn has a housing 1C. Furthermore, a removable output magazine 24 is arranged on the housing 1B. Media 3 to be printed on can be arranged in the housing 1C of the input magazine in order to be fed to a printing unit of the printer according to FIG. 3. The media 3 to be printed on may be films, plates, strips or signs, in particular rigid media to be printed on. In the input magazine of the present case, a stack of media 3 to be printed on that has not been printed on can be fed to the printing unit. In the output magazine 24, the printed-on media 3 to be printed on are collected, in this case once again in a stack.

The printer further comprises a display 27 which is designed and configured as a control panel for entering commands. The display 27 represents an electronic component.

The housing 1B is made of the material described herein and by the method described herein, in each case of any configuration.

FIG. 4 shows the housing 1C of the input magazine for the printer according to FIG. 3 in a separate illustration. The housing 1C has a cover 11. The cover 11 and the remaining housing 1C are each made of a material as described herein and by the method described herein, in each case of any configuration. The cover 11 consists of a first material and at least part of the remaining housing 1C consists of a second material, wherein the first and the second material differ from one another. In this case, the cover 11 is made of a renewable raw material which is biodegradable and transparent. The rest of the housing 1C is made of a polymeric secondary raw material and is not transparent. In this example, the transparency allows a fill level of the media 3 to be printed on to be checked when the cover 11 is closed. Optionally, the transparent cover 11 has a degree of opacity of 0.6 haze according to ASTM D 1033.

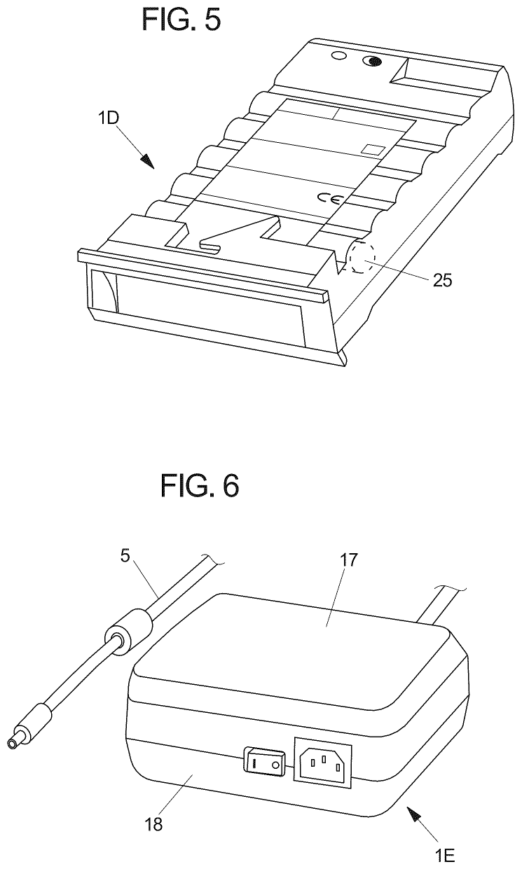

FIG. 5 shows another housing 1D for an electrical device in the form of an accumulator, e.g., the printer according to FIG. 3. The housing 1D accommodates a plurality of rechargeable battery cells 25, one of which is illustrated as an example in FIG. 5.

The housing 1D is made of the material described herein and by the method described herein, in each case of any configuration.

FIG. 6 shows another housing 1E for an electrical device in the form of a power supply unit, e.g., of the printer according to FIG. 3. The housing 1E accommodates a plurality of electrical components, such as a transformer or the like. Further electrical components in the form of a cable 5 connected to the housing 1E, a power switch and a socket for a plug connector are illustrated in FIG. 6.

The housing 1E has a first housing part 17 in the form of an upper shell and a second housing part 18 in the form of a lower shell, which together define an interior space. Both housing parts 17, 18 are made of the material described herein and by the method described herein, in each case of any desired configuration. Both housing parts 17, 18 in the example shown are made of the same material.

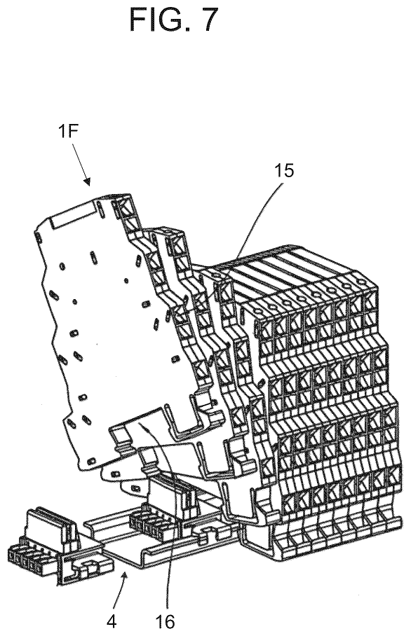

FIG. 7 shows an arrangement of planar housings 1F representing a plurality of further examples of housings, each of which serves as a conductor support. The housings 1F are or can be arranged in a row on a mounting rail 4.

The individual housings 1F are each configured and designed as industrial electronics housings for housing electrical and electronic components, which are or can be connections 15 (representatively marked once in FIG. 7), circuit carriers such as printed circuit boards, electrical and electronic components, including as components of a printed circuit board assembly. The connections 15 are used to connect cables for transmitting electrical current, data and/or signals and are configured and designed accordingly.

Each housing 1F has a locking foot 16, by means of which each housing 1F can be locked to the mounting rail 4. The housings 1F have electrical connections that are either connected directly to one another or to the aforementioned components, in particular a printed circuit board, via conductors inside the housing 1F.

It has surprisingly been found that the housing 1A-1F described herein allows for the same level of implementation quality as a conventional production process despite a reduced carbon footprint. It has surprisingly been found, for example, that polymers consisting of a secondary raw material can be used, which represent an equivalent substitute for a polymer made from a fossil raw material. The housings 1A-1F described herein provide the advantage that recycled polymers can be used for high-quality products, components or assemblies, as well as portions thereof, and their use is not confined to packaging purposes or applications with low requirements. In this respect, the housings 1A-1F described herein make it possible to significantly reduce the CO2 impact on the environment by opening up a wide range of applications for secondary polymers.

It is optionally provided that at least the compostable/biodegradable polymer fulfills at least the requirements according to the version of DIN CERTCO DIN EN 13432 valid in 2021.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1A-1F Housing
10 Outer wall
11 Cover
12 Opening
13 Predetermined breaking point
14 Fastening point
15 Connection
16 Locking foot
17 First housing part
18 Second housing part
2 Electrical device
20 Electrical component
21 Printing unit
22 Media holder
23 Movable part
24 Output magazine
25 Battery cell
27 Display
3 Medium to be printed on
4 Mounting rail
5 Cable

1. A housing for an electrical device, comprising:
a material comprising a plastics material, the plastics material comprising at least one of:
a polymeric secondary raw material,
a biodegradable polymer, and
a bio-based polymer.

2. The housing of claim 1, wherein the material comprises a plurality of different plastics materials, each different plastic material of the plurality of different plastics materials at least one of:
comprising a polymeric secondary raw material,
comprising synthesis gas/liquids/reactants comprising at least one of renewable sources and biological sources, and
being biodegradable.

3. The housing of claim 1, wherein the housing comprises a plurality of different materials, at least one different material of the plurality of different materials at least one of:
comprising a plastics material comprising polymeric secondary raw material,
comprising bio-based polymer synthesis gas/liquids/reactants comprising at least one of renewable sources and biological sources, and
being biodegradable.

4. The housing of claim 1, wherein the polymeric secondary raw material comprises at least one of a conventionally recycled thermoplastic and a chemically recycled thermoplastic.

5. The housing of claim 4, wherein the material comprises at least 20 wt. %, of the plastics material, and
wherein the plastics material comprises at least one of a conventionally recycled thermoplastic and a chemically recycled thermoplastic.

6. The housing of claim 4, wherein the polymeric secondary raw material is comprises at least one of a conventionally recycled thermoplastic and a chemically recycled thermoplastic, and
wherein each of the conventionally recycled thermoplastic and the chemically recycled thermoplastic comprises at least one of an engineering, standard, or high-performance thermoplastic and a thermoplastic elastomer comprising at least one of polyurethane, TPU, TPS, polycarbonate, polyamide, polyethylene, polyethylene terephthalate, polyvinyl chloride, polybutylene terephthalate, polyester, polypropylene, and their blends and copolymers.

7. The housing of claim 1, wherein 10 to 100 wt. % of the material comprises plastics material produced from biological polymer synthesis gas/liquids/reactants comprising at least one of renewable sources and biological sources.

8. The housing of claim 1, wherein the plastics material of the material comprises synthesis gas/liquids/reactants comprising at least one of:
renewable sources and biological sources,
synthesis gas/liquids/reactants comprising at least one of renewable sources and biological sources, the synthesis gas/liquids/reactants comprising at least one of sugar, starch, protein, cellulose, lignin, fat, and vegetable oil.

9. The housing of claim 1, wherein the plastics material of the material comprises synthesis gas/liquids/reactants comprising at least one of renewable sources and biological sources, and
wherein the plastics material comprises at least one of:
polylactide,
polyhydroxy alkanoate,
cellulose derivative, comprising cellulose ester or cellulose butyrate, polyethylene, starch derivative, polyurethane, TPU, TPS, polycarbonate, polyamide, polyethylene, polyethylene terephthalate, polyvinyl chloride, polybutylene terephthalate, polyester and polypropylene,
blends and copolymers thereof.

10. The housing of claim 1, wherein the plastics material of the material is biodegradable and comprises polybutylene adipate terephthalate, polyhydroxy alkanoate, polylactide, starch blend, or polyester.

11. The housing of claim 1, further comprising:
a fastening point for a component, the fastening point being connected to a remainder of the housing via a predetermined breaking point.

12. The housing of claim 1, wherein the housing comprises a printer housing and has an opening for inserting and/or removing a medium to be printed on.

13. An electrical device, comprising:
the housing to claim 1; and
electrical components and/or electronic components arranged in and/or on the housing.

14. The electrical device of claim 13, further comprising:
a printing unit for printing on a medium to be printed on.

15. The electrical device of claim 14, further comprising:
a media receptacle configured to at least one of hold and convey the medium to be printed on during printing by the printing unit, the media holder and the printing unit being configured such that rigid media to be printed on can be printed on.

16. The electrical device to claim 15, wherein the media holder and the printing unit are configured such that plastics- or metal-based rigid media to be printed on comprising plates, strips, or signs can be printed on.

17. The electrical device of claim 13, wherein movable parts are arranged in or on the housing,
wherein the movable parts comprise a material comprising a plastics material comprising a polymeric secondary raw material, the polymeric secondary raw material comprising synthesis gas/liquids/reactants at least one of comprising at least one of renewable sources and biological sources and being biodegradable.

18. The electrical device of claim 13, wherein at least one electrical and/or electronic component arranged in the housing is fastened to the housing via a predetermined breaking point of the housing.

19. A method for producing a housing for an electrical device, the method comprising:
providing a material comprising a plastics material, the plastics material at least one of comprising a recycled thermoplastic, comprising synthesis gas/liquids/reactants comprising at least one of renewable sources and biological sources, being biodegradable; and
shaping the housing from the material, at least in part.

20. The method of claim 19, wherein the plastics material is produced by chemically recycling a thermoplastic.

21. The method of claim 20, wherein chemically recycling the thermoplastic comprises at least one of solvolysis, depolymerization, pyrolysis, and gasification.

22. A method for producing an electronic device, comprising:
producing a housing using the method of claim 19; and
arranging at least one electrical and/or electronic component in the housing.
